(19) United States
(12) Patent Application Publication
(10) Pub. No.: US 2024/0118969 A1
(43) Pub. Date: Apr. 11, 2024

(54) STORAGE ABNORMALITY DETECTION DEVICE, STORAGE ABNORMALITY DETECTION METHOD, AND COMPUTER-READABLE STORAGE MEDIUM

(71) Applicant: TOYOTA JIDOSHA KABUSHIKI KAISHA, Toyota-shi (JP)

(72) Inventors: Junichiro TAMAO, Tokyo-to (JP); Takahiro UTSUNOMIYA, Tokyo-to (JP); Takumi HORIE, Chofu-shi (JP); Tomoaki KARASAWA, Matsudo-shi (JP)

(73) Assignee: TOYOTA JIDOSHA KABUSHIKI KAISHA, Toyota-shi (JP)

(21) Appl. No.: 18/371,798

(22) Filed: Sep. 22, 2023

(30) Foreign Application Priority Data
Oct. 6, 2022 (JP) 2022-161973

(51) Int. Cl. G06F 11/10

(52) U.S. Cl. CPC G06F 11/1048; G06F 11/1044

(57) ABSTRACT

A storage controller performs a storage write operation, and stores being unable to write due to memory cell deterioration in cases in which bit flips uncorrectable by an ECC have been detected a predetermined number of times or more for each predetermined volume written and also writing of a TBW or greater has been confirmed.

### CROSS-REFERENCE TO RELATED APPLICATION

This application is based on and claims priority under 35 USC § 119 from Japanese Patent Application No. 2022-161973 filed on Oct. 6, 2022, the disclosure of which is incorporated by reference herein.

### BACKGROUND

### Technical Field

The present disclosure is related to a storage abnormality detection device, a storage abnormality detection method, and a computer-readable storage medium.

### Related Art

An electronic control device proposed in Japanese Patent Application Laid-Open (JP-A) No. 2016-170604 (Patent Document 1) includes: a means for a processing section to write data satisfying a write execution condition to a data storage area of a memory; a means to count a number of write times to the memory for each data written to the memory during each operation period of the processing section, a means to, when an operation stop condition is satisfied and prior to stopping operation of the processing section, update and write a value resulting from adding a maximum value from out of number of write times counted in a current operation period to a value stored in a number of times storage area of the memory by writing as a maximum number of write times to the number of times storage area, and a means to determine whether or not a lifespan of the memory has expired based on the maximum number of write times stored in the number of times storage area.

A memory having a total written amount limit is able to be written to without problems when writing to the memory is performed up to a pre-set limit, such as a total bytes written (TBW). The total written amount limit is set while considering safety, and so memory lifespan expiration is determined when the limit is reached, as in Patent Document 1, resulting in a memory abnormality being determined by lifespan even though the memory is still useable.

### SUMMARY

In consideration of the above circumstances, an object of the present disclosure is to provide a storage abnormality detection device, a storage abnormality detection method, and a computer-readable storage medium that enable a memory to be more effectively utilized than cases in which abnormality determination is by total written amount.

A storage abnormality detection device according to a first aspect includes a memory having a total written amount limit, and a determination section configured to determine an abnormality of the memory in cases in which errors uncorrectable by a correction section that detects and corrects errors occurring in the memory have been detected a predetermined number of times or more in a predetermined period.

In the first aspect, errors occurring in the memory having the total written amount limit are detected and corrected by the correction section.

The determination section determines there to be an abnormality of the memory in cases in which errors uncorrectable by the correction section have been detected the predetermined number of times or more in the predetermined period. Abnormality determination is performed by determining whether or not the memory is actually writeable to by checking uncorrectable errors in this manner, enabling the memory to be more effectively utilized than cases in which abnormality determination is by total written amount.

A storage abnormality detection device according to a second aspect is the storage abnormality detection device according to the first aspect, wherein the determination section determines an abnormality of the memory in cases in which errors uncorrectable by the correction section have been detected the predetermined number of times or more in the predetermined period and also a total written amount of the memory is a predetermined upper limit value or greater.

In the second aspect, the total written amount is checked in addition to checking the uncorrectable errors, thereby enabling more accurate determination of memory abnormality than cases in which abnormality determination is by checking one only thereof.

A storage abnormality detection device according to a third aspect is the storage abnormality detection device according to the first aspect, wherein the determination section determines an abnormality of the memory in cases in which errors uncorrectable by the correction section have been detected the predetermined number of times or more in the predetermined period and also a predetermined manufacturer's warranty period or predetermined manufacturer's warranty distance has been exceeded.

In the third aspect, the manufacturer's warranty period or the manufacturer's warranty distance is checked in addition to checking the uncorrectable errors, thereby enabling more accurate determination of memory abnormality than cases in which abnormality determination is by checking one only thereof.

A storage abnormality detection device according to a fourth aspect is the storage abnormality detection device according to any one of the first aspect to the third aspect, wherein in cases in which the memory is utilized in a function related to vehicle travel, a function related to regulations, or a function related to security, the storage abnormality detection device further includes a notification section configured to notify an abnormality of the memory in cases in which an abnormality of the memory has been determined by the determination section.

In the fourth aspect, immediate replacement of the memory can be prompted when an abnormality is determined for cases in which the memory is utilized in a function related to vehicle travel, a function related to regulations, or a function related to security.

A storage abnormality detection device according to a fifth aspect is the storage abnormality detection device according to the second aspect, wherein the determination section checks the total written amount of the memory prior to performing a write operation to the memory, and in cases in which the total written amount of the memory is less than a predetermined upper limit value, determines an abnormality caused by something other than the limit in cases in which errors uncorrectable by the correction section have been detected the predetermined number of times or more in the predetermined period.

The fifth aspect enables an abnormality caused by something other than an abnormality of writing to the memory to be detected.

A storage abnormality detection method according to a sixth aspect is a method in which a computer performs processing including detecting errors uncorrectable by a correction section that detects and corrects errors occurring in a memory having a total written amount limit, and determining an abnormality of the memory in cases in which the uncorrectable errors have been detected a predetermined number of times or more in a predetermined period of time.

The sixth aspect enables provision of a storage abnormality detection method that enables a memory to be more effectively utilized than cases in which abnormality determination is by total written amount.

A storage abnormality detection program recorded on a computer-readable storage medium according to a seventh aspect causes a computer to execute processing including detecting errors uncorrectable by a correction section that detects and corrects errors occurring in a memory having a total written amount limit, and determining an abnormality of the memory in cases in which the uncorrectable errors have been detected a predetermined number of times or more in a predetermined period of time.

The seventh aspect provides a storage abnormality detection program that enables a memory to be more effectively utilized than cases in which abnormality determination is by total written amount.

As described above, the present disclosure enables provision of a storage abnormality detection device, a storage abnormality detection method, and a computer-readable storage medium that enable a memory to be more effectively utilized than cases in which abnormality determination is by total written amount.

### BRIEF DESCRIPTION OF DRAWINGS

Exemplary embodiments of the present disclosure will be described in detail based on the following figures, wherein:

FIG. 1 is a diagram illustrating a schematic configuration of a vehicle control system according to an exemplary embodiment;

FIG. 2 is a block diagram illustrating an example of a configuration of a microcomputer;

FIG. 3 is a block diagram illustrating a storage controller and flash memory included in a central ECU;

FIG. 4 is a flowchart illustrating an example of a flow of processing performed in a storage controller of a central ECU in a vehicle control system according to a first exemplary embodiment;

FIG. 5 is a flowchart illustrating an example of a flow of processing performed in a storage controller of a central ECU in a vehicle control system according to a second exemplary embodiment;

FIG. 6 is a flowchart illustrating an example of a flow of processing performed in a storage controller of a central ECU in a vehicle control system according to a third exemplary embodiment;

FIG. 7 is a flowchart illustrating an example of a flow of processing performed in a storage controller of a central ECU in a vehicle control system according to a fourth exemplary embodiment; and

FIG. 8 is a flowchart illustrating a flow of processing at a connection point A.

### DETAILED DESCRIPTION

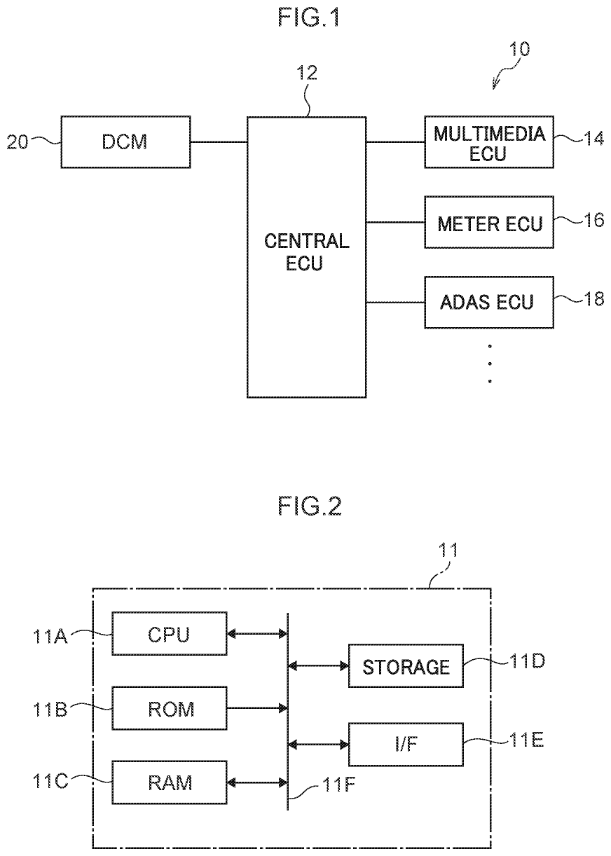

Detailed description follows regarding an example of an exemplary embodiment of the present disclosure, with reference to the drawings. In the present exemplary embodiment an example will be described of a vehicle control system installed to a vehicle. FIG. 1 is a diagram illustrating a schematic configuration of a vehicle control system according to the present exemplary embodiment.

As illustrated in FIG. 1, a vehicle control system 10 according to the present exemplary embodiment includes a central electronic control unit (ECU) 12 to control a vehicle overall. The central ECU 12 functions as an example of a storage abnormality detection device.

Plural ECUs and a data communication module (DCM) 20 are connected to the central ECU 12. Examples of the plural connected ECUs include a multimedia ECU 14, a meter ECU 16, an advance driver assistance system (ADAS) ECU 18, and the like.

The multimedia ECU 14 controls plural media such as text, audio, still images, videos, and the like. The multimedia ECU 14 performs, for example, processing to acquire images captured by a camera or the like, to perform processing on the acquired images, and to display them on a display, meter, or the like. More specifically, during a parking operation, the multimedia ECU 14 performs processing on images captured by a camera to produce an image from a perspective of looking down on a vehicle from above, and processing such as to display the processed images on a display.

The meter ECU 16 performs processing to display plural meters on a meter display installed to an instrument panel, and processing to display various vehicle information. In cases in which an abnormality or the like has occurred in the vehicle, the meter ECU 16 notifies an occupant that the abnormality has occurred by performing display on the meter display.

The ADAS ECU 18 acquires surrounding information detected by various sensors monitoring the surroundings, such as a camera, radar, or the like, provides the surrounding information to other ECUs, and includes a function to control the steering and brakes when required.

The DCM 20 is a module that performs communication with external devices using wireless communication with a public network and performs communication using, for example, a communication standard such as a mobile phone standard or the like.

As illustrated in FIG. 2, the central ECU 12, the plural ECUs, and the DCM 20 are each configured including a general microcomputer 11 that includes a central processing unit (CPU) 11A, read only memory (ROM) 11B, random access memory (RAM) 11C, a storage 11D, an interface (I/F) 11E, a bus 11F, or the like. Namely, control of the vehicle, and control such as storage 11D abnormality detection, is performed by the CPU 11A expanding various programs stored on the ROM 11B, storage 11D, and the like into the RAM 11C, and executing the programs.

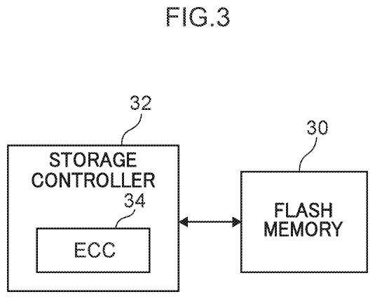

As illustrated in FIG. 3, the central ECU 12 includes a storage controller 32 serving as an example of a determination section and a flash memory 30 serving as an example of a memory. The flash memory 30 is included as an example of the storage 11D, and reading and writing thereto is controlled by the storage controller 32. As an example, a NAND flash memory may be applied as the flash memory 30.

An error checking and correcting (ECC) 34 is included as an example of a correction section in the storage controller 32, and functions to detect and automatically correct errors that occurred in the flash memory 30. The ECC 34 handles appending error correction reference numbers and verification during data transmission, and detects and corrects errors in the data.

For memory such as NAND flash memory having a total written amount limit, a lifespan thereof is limited by the total written amount. Due to no longer being able to write when the lifespan has expired, there is a need to notify applications that use the memory in cases in which the lifespan has completely expired, and when faults and abnormalities are detected.

Hitherto as a lifespan detection method, a total bytes written (TBW) is set in advance as a written upper limit value, and the lifespan expiration is determined in cases in which the total written amount has reached the TBW.

However, even when writing has been performed to the memory up to the TBW, writing can still be performed without problems. Due to considering variation between individual memories, worst case usage environments, and a safety factor when deciding the TBW value, the lifespan expiration is sometimes detected much earlier than when writing actually no longer becomes possible due to deteriorations in memory cells, such that a memory is unable to be utilized effectively.

However, in the storage controller 32 of the central ECU 12, an abnormality in the flash memory 30 is determined in cases in which uncorrectable errors have been detected by the ECC 34 a predetermined number of times or more in a predetermined period of time.

### First Exemplary Embodiment

In the present exemplary embodiment, an abnormality of the memory is determined in cases in which uncorrectable errors have been detected by the ECC 34 the predetermined number of times or more in the predetermined period of time (for example, in each predetermined volume written) and also the total written amount has exceeded the TBW. This thereby enables the memory to be more effectively utilized than cases in which abnormality in the flash memory 30 is determined by TBW.

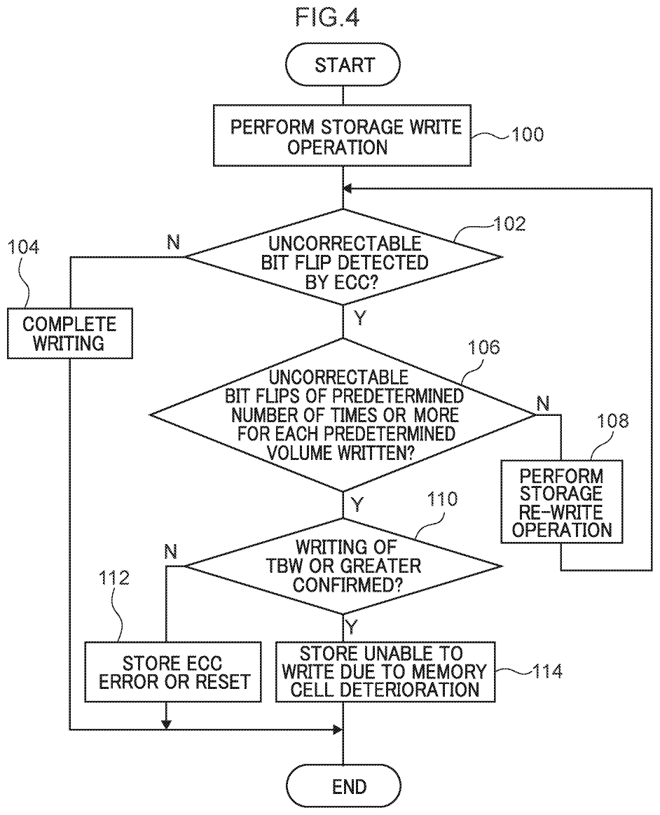

Description next follows regarding processing performed by the storage controller 32 of the central ECU 12 in the vehicle control system 10 according to the present exemplary embodiment configured as described above. FIG. 4 is a flowchart illustrating an example of a flow of processing performed by the storage controller 32 of the central ECU 12 in the vehicle control system 10 according to the present exemplary embodiment. Note that the processing of FIG. 4 is, for example, started when writing to the flash memory 30 has been instructed using a file organizing application programming interface (API) or the like.

At step 100 the storage controller 32 performs a storage write operation and then transitions to step 102. Namely, performs a write operation to the flash memory 30.

At step 102, the storage controller 32 determines whether or not an uncorrectable bit flip has been detected by the ECC 34. Processing transitions to step 104 in cases in which this determination is negative, and processing transitions to step 106 in cases in which this determination is affirmative.

At step 104, the storage controller 32 completes writing to the flash memory 30 and ends a cycle of processing.

At step 106, the storage controller 32 determines whether or not an uncorrectable bit flip has occurred the predetermined number of times or more for each predetermined volume written. This determination is, for example, determination as to whether or not an uncorrectable bit flip has occurred the predetermined number of times or more for each predetermined number of times. Processing transitions to step 108 in cases in which this determination is negative, and processing transitions to step 110 in cases in which this determination is affirmative.

At step 108, the storage controller 32 performs a storage re-write operation, and then returns to step 102 and repeats the processing described above.

Moreover, at step 110, the storage controller 32 determines whether or not writing of the TBW or greater has been confirmed. This determination may, for example, be determination as to whether or not the volume written is the TBW or greater by checking driver information, or may be determination by checking something other than driver information. Processing transitions to step 112 in cases in which this determination is negative, and processing transitions to step 114 in cases in which this determination is affirmative.

At step 112, the storage controller 32 stores an ECC error (for example, a fault code (diagnostic trouble code (DTC)) or resets, and ends a cycle of processing.

At step 114 the storage controller 32 stores being unable to write due to memory cell deterioration as a record of behavior (RoB) in the vehicle, then ends one cycle of processing.

By performing such processing, the flash memory 30 determines an abnormality in cases in which uncorrectable errors have been detected by the ECC 34 the predetermined number of times or more in the predetermined period of time. This thereby enables the memory to be utilized more effectively than cases of abnormality determination by TBW alone. Moreover, checking the TBW in addition to checking the ECC 34 enables certain detection of abnormalities in the flash memory 30.

Note that although in the processing of FIG. 4 the TBW is checked in addition to checking the ECC 34, checking of the ECC 34 alone is sufficient. Namely, an abnormality of the flash memory 30 may be determined merely by determining whether or not uncorrectable errors have been detected by the ECC 34 the predetermined number of times or more for each predetermined volume written. In such cases the processing of step 110 and step 112 of FIG. 4 is omitted.

In the present exemplary embodiment, in cases in which memory cell deterioration is determined by checking the ECC 34 and checking the TBW, this is stored in the information of the vehicle without being directly notified to the occupant, and this is applicable to cases in which “travel”, “turn”, “stop” are not affected even when storage is no longer writeable.

### Second Exemplary Embodiment

Description next follows as a second exemplary embodiment of another example of processing performed in the storage controller 32 of the central ECU 12 in the vehicle control system 10 configured as described above.

In the first exemplary embodiment, the TBW is checked in addition to checking the ECC 34, however the present exemplary embodiment is configured to check a manufacturer's warranty period or a manufacturer's warranty distance, instead of checking the TBW of the first exemplary embodiment.

The present exemplary embodiment uses another logic, and applied to cases in which storage writing of the TBW or greater is suppressed during the manufacturer's warranty period or the manufacturer's warranty distance. Note that the manufacturer's warranty period and the manufacturer's warranty distance differs depending on the vehicle, such as a passenger car, taxi, commercial vehicle, or the like.

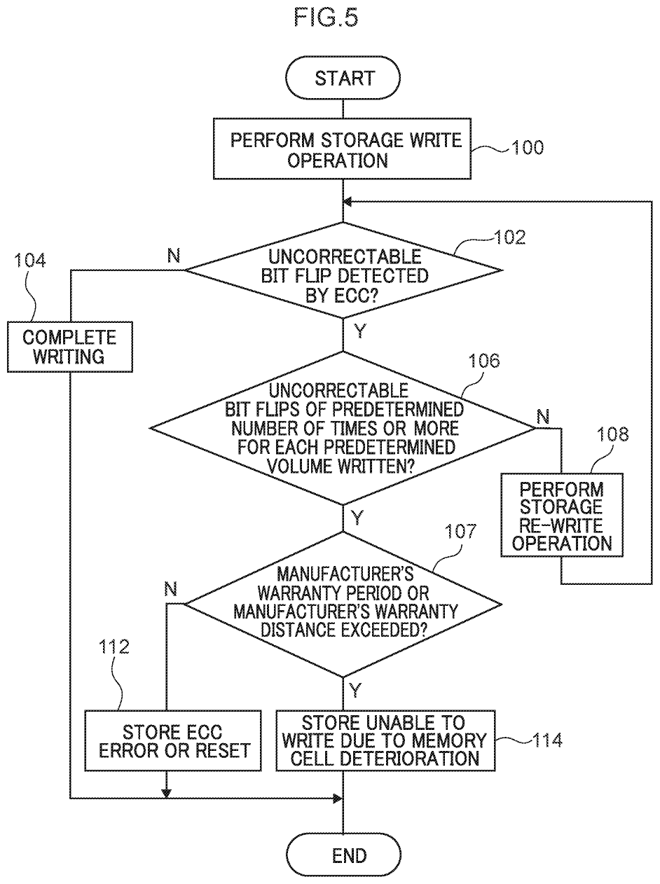

FIG. 5 is a flowchart illustrating an example of a flow of processing performed by the storage controller 32 of the central ECU 12 in the vehicle control system 10 according to the present exemplary embodiment. Note that the processing of FIG. 5 may, for example, be started when writing to the flash memory 30 has been instructed using a file organizing API or the like. Moreover, in the description the same reference numerals will be appended to the same processing as FIG. 4.

At step 100, the storage controller 32 performs a storage write operation and transitions processing to step 102. Namely, performs a write operation to the flash memory 30.

At step 102, the storage controller 32 determines whether or not an uncorrectable bit flip has been detected by the ECC 34. Processing transitions to step 104 when this determination is negative, and processing transitions to step 106 when this determination is affirmative.

At step 104, the storage controller 32 completes writing to the flash memory 30 and ends a cycle of processing.

At step 106, the storage controller 32 determines whether or not an uncorrectable bit flip has occurred the predetermined number of times or more for each predetermined volume written. This determination is, for example, determination as to whether or not an uncorrectable bit flip has occurred the predetermined number of times or more for each predetermined number of times. Processing transitions to step 108 in cases in which this determination is negative, and processing transitions to step 107 in cases in which this determination is affirmative.

At step 108, the storage controller 32 performs a storage re-write operation, and then returns to step 102 and repeats the processing described above.

At step 107, the storage controller 32 determines whether or not a predetermined manufacturer's warranty period has expired, or determines whether or not a predetermined manufacturer's warranty distance or greater has been travelled. Processing transitions to step 112 when this determination is negative, and processing transitions to step 114 when this determination is affirmative.

At step 112, the storage controller 32 stores an ECC error (for example, a fault code (diagnostic trouble code (DTC)) or resets, and ends a cycle of processing.

At step 114 the storage controller 32 stores being unable to write due to memory cell deterioration as a record of behavior (RoB) in the vehicle, then ends one cycle of processing.

Performing such processing enables, similarly to in the previously described exemplary embodiment, memory to be more effectively utilized than when abnormality is determined by TBW. Moreover, checking the manufacturer's warranty period or the manufacturer's warranty distance in addition to checking the ECC 34 enables certain detection of abnormalities in the flash memory 30.

### Third Exemplary Embodiment

As a third exemplary embodiment, description follows regarding another example of processing performed by the storage controller 32 of the central ECU 12 in the vehicle control system 10 configured as described above.

In the present exemplary embodiment description follows regarding application to a case in which a memory is utilized in a function related to vehicle travel, such as “moving”, “turning”, “stopping”, or the like, a function related to regulations, or a function related to security such as important security measures and the like. Namely, although in each of the exemplary embodiments described above information was stored in the vehicle without notification when a deterioration of memory cells was determined, in the present exemplary embodiment the storage controller 32 functions as a notification section, and is configured so as to notify an abnormality of the flash memory 30 to an occupant.

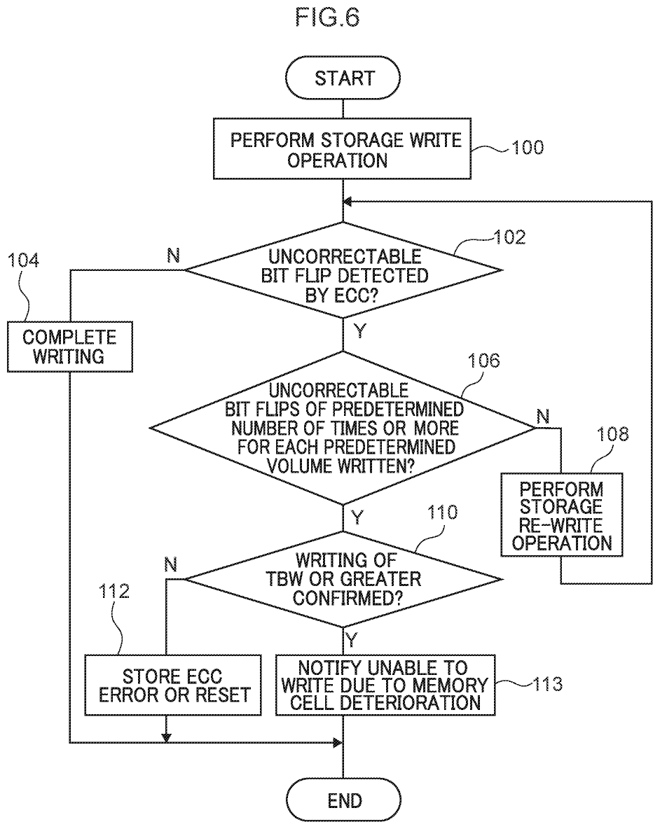

FIG. 6 is a flowchart illustrating an example of a flow of processing performed by a storage controller 32 of a central ECU 12 in a vehicle control system 10 according to the present exemplary embodiment. Note that the processing of FIG. 6 may, for example, be started when writing to the flash memory 30 has been instructed using a file organizing API or the like. Moreover, in the description the same reference numerals will be appended to the same processing as FIG. 4.

At step 100, the storage controller 32 performs a storage write operation and transitions processing to step 102. Namely, performs a write operation to the flash memory 30.

At step 102, the storage controller 32 determines whether or not an uncorrectable bit flip has been detected by the ECC 34. Processing transitions to step 104 when this determination is negative, and processing transitions to step 106 when this determination is affirmative.

At step 104, the storage controller 32 completes writing to the flash memory 30 and ends a cycle of processing.

At step 106, the storage controller 32 determines whether or not an uncorrectable bit flip has occurred the predetermined number of times or more for each predetermined volume written. This determination is, for example, determination as to whether or not an uncorrectable bit flip has occurred the predetermined number of times or more for each predetermined number of times. Processing transitions to step 108 in cases in which this determination is negative, and processing transitions to step 110 in cases in which this determination is affirmative.

At step 108, the storage controller 32 performs a storage re-write operation, and then returns to step 102 and repeats the processing described above.

As step 110, the storage controller 32 determines whether or not writing of the TBW or greater has been confirmed. This determination may, for example, be determination as to whether or not the volume written is the TBW or greater by checking driver information, or may be determination by checking something other than driver information. Processing transitions to step 112 in cases in which this determination is negative, and processing transitions to step 113 in cases in which this determination is affirmative.

At step 112, the storage controller 32 stores an ECC error (for example, a fault code (diagnostic trouble code (DTC)) or resets, and ends a cycle of processing.

At step 113, the storage controller 32 notifies being unable to write due to memory cell deterioration, then ends one cycle of processing. In the present exemplary embodiment, by notifying the meter ECU 16, the meter ECU 16 performs a warning display or the like to indicate a memory abnormality so as to notify the memory abnormality to the occupant. This thereby enables immediate replacement of the memory to be prompted.

Note that although in the present exemplary embodiment, similarly to in the first exemplary embodiment, memory cell deterioration is determined by checking the TBW in addition to checking the ECC 34, memory cell deterioration may be determined by checking the manufacturer's warranty period or the manufacturer's warranty distance in addition to checking the ECC 34 as in the second exemplary embodiment.

### Fourth Exemplary Embodiment

Next, as a fourth exemplary embodiment, description follows regarding another example of processing performed by the storage controller 32 of the central ECU 12 in the vehicle control system 10 configured as described above.

The present exemplary embodiment is configured so as to perform checking of the TBW prior to performing a write operation. Note that in the following description a case is described in which the processing of the third exemplary embodiment is changed so as to perform checking of the TBW prior to performing a write operation, however other exemplary embodiments may also be changed in a similar manner to in the following processing so as to perform the checking of the TBW prior to performing a write operation.

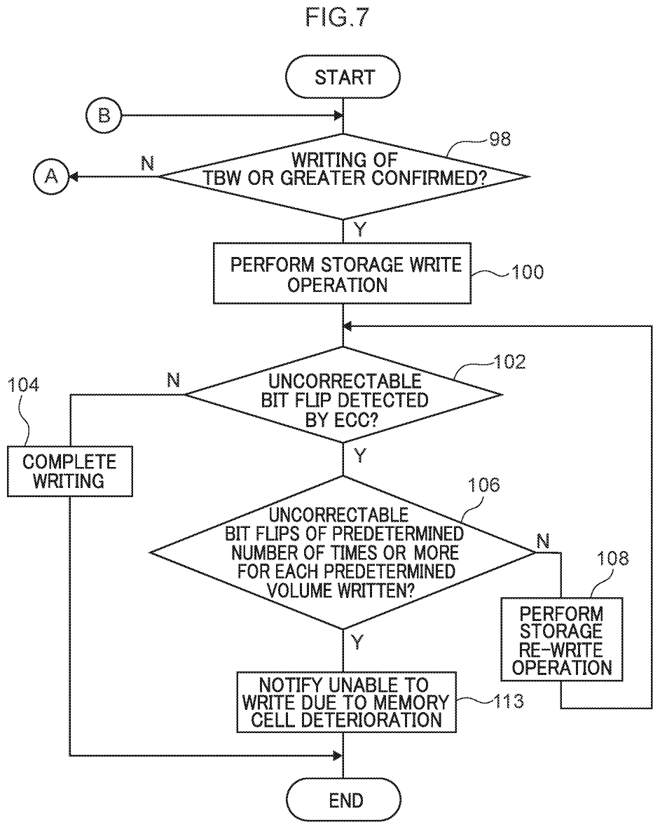

FIG. 7 is a flowchart illustrating an example of a flow of processing performed in a storage controller 32 of a central ECU 12 in a vehicle control system according 10 to the present exemplary embodiment. Note that the processing of FIG. 7 may, for example, be started when writing to the flash memory 30 has been instructed using a file organizing API or the like. Moreover, in the description the same reference numerals will be appended to the same processing as FIG. 6.

At step 98, the storage controller 32 determines whether or not writing of the TBW or greater has been confirmed. This determination may, for example, be determination as to whether or not the volume written is the TBW or greater by checking driver information, or may be determination by checking something other than driver information. Processing transitions to step 100 in cases in which this determination is affirmative, and processing transitions to connection point A in cases in which this determination is negative. Note that details regarding the processing of connection point A will be described later.

At step 100, the storage controller 32 performs a storage write operation and transitions processing to step 102. Namely, performs a write operation to the flash memory 30.

At step 102, the storage controller 32 determines whether or not an uncorrectable bit flip has been detected by the ECC 34. Processing transitions to step 104 when this determination is negative, and processing transitions to step 106 when this determination is affirmative.

At step 104, the storage controller 32 completes writing to the flash memory 30 and ends a cycle of processing.

At step 106, the storage controller 32 determines whether or not an uncorrectable bit flip has occurred the predetermined number of times or more for each predetermined volume written. This determination is, for example, determination as to whether or not an uncorrectable bit flip has occurred the predetermined number of times or more for each predetermined number of times. Processing transitions to step 108 in cases in which this determination is negative, and processing transitions to step 113 in cases in which this determination is affirmative.

At step 108, the storage controller 32 performs a storage re-write operation, and then returns to step 102 and repeats the processing described above.

Moreover, at step 113, the storage controller 32 notifies being unable to write due to memory cell deterioration, then ends one cycle of processing. In the present exemplary embodiment, by notifying the meter ECU 16, the meter ECU 16 performs a warning display or the like to indicate a memory abnormality so as to notify the memory abnormality to the occupant.

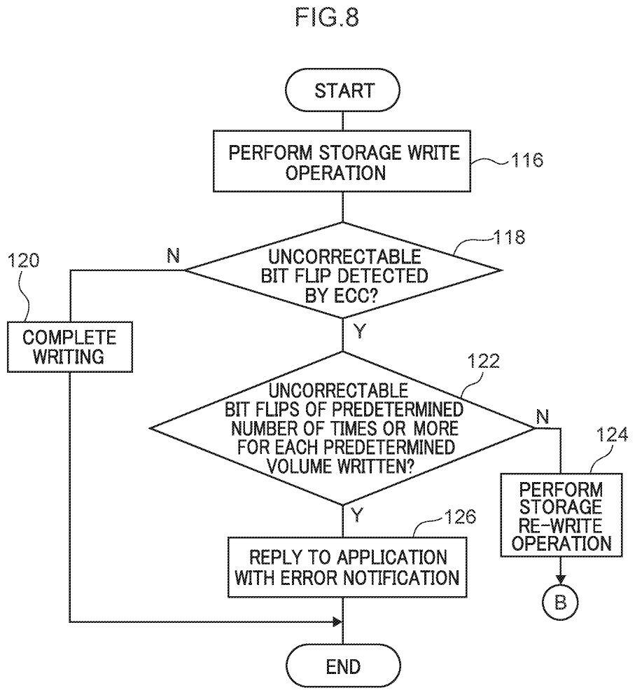

Processing transitions to the connection point A when negative determination is made at step 98, and thereby transitions to step 116 of FIG. 8. FIG. 8 is a flowchart illustrating a flow of processing at the connection point A.

At step 116, the storage controller 32 performs a storage write operation, and then transitions to step 118. Namely, performs a write operation to the flash memory 30.

At step 118, the storage controller 32 determines whether or not an uncorrectable bit flip has been detected by the ECC 34. Processing transitions to step 120 when this determination is negative, and processing transitions to step 122 when this determination is affirmative.

At step 120, the storage controller 32 completes writing to the flash memory 30 and ends a cycle of processing.

At step 122, the storage controller 32 determines whether or not an uncorrectable bit flip has occurred the predetermined number of times or more for each predetermined volume written. This determination is, for example, determination as to whether or not an uncorrectable bit flip has occurred the predetermined number of times or more for each predetermined number of times. Processing transitions to step 124 in cases in which this determination is negative, and processing transitions to step 126 in cases in which this determination is affirmative.

At step 124, the storage controller 32 performs a storage re-write operation and then transitions to connection point B, and thereby returns to step 98 of FIG. 7, and repeats the processing described above.

At step 126, the storage controller 32 replies to an application with an error notification, and ends one cycle of processing. Namely, without writing of the TBW or greater being confirmed, an abnormality caused by something other than the memory is determined in cases in which a bit flip uncorrectable by the ECC has occurred the predetermined number of times or more for each predetermined volume written, and an error is notified to an application.

Performing such processing also, similarly to in the above exemplary embodiments, enables memory to be more effectively utilized than when abnormality is determined by TBW. Moreover, an abnormality of the flash memory 30 can be detected with certainty by checking the manufacturer's warranty period or the manufacturer's warranty distance in addition to checking the ECC 34. The present exemplary embodiment moreover enables detection of an abnormality caused by something other than an abnormality in writing to memory.

Note that in the exemplary embodiment described above, description is of an example in which a NAND flash memory is applied as an example of flash memory, however there is no limitation to being a NAND flash memory. For example, application may be made to a NOR flash memory, and application may be made to any other memory having a total written amount limit.

Moreover, although in the exemplary embodiment described above the ECC 34 is described for an embodiment included in the storage controller 32, there is no limitation thereto. For example, the ECC 34 may be an embodiment provided externally to the storage controller 32, or may be an embodiment implemented by software.

Moreover, although the processing performed by the storage controller 32 in each of the exemplary embodiment described above has been described as software processing performed by executing a program, there is no limitation thereto. For example, such processing may be performed by hardware such as a graphics processing unit (GPU), application specific integrated circuit (ASIC), a field programmable gate array (FPGA), or the like. Or may be processing performed by a combination of both software and hardware. In cases in which processing is performed by software, a program may be distributed stored on various storage media.

Furthermore, the present disclosure is not limited by the points made above, and obviously various modifications other than those of the points made above may also be implemented within a range not departing from the spirit of the present disclosure.

What is claimed is:

1. A storage abnormality detection device comprising:
a memory having a total written amount limit; and
a determination section configured to determine an abnormality of the memory in cases in which errors uncorrectable by a correction section that detects and corrects errors occurring in the memory have been detected a predetermined number of times or more in a predetermined period.

2. The storage abnormality detection device of claim 1, wherein the determination section determines an abnormality of the memory in cases in which errors uncorrectable by the correction section have been detected the predetermined number of times or more in the predetermined period and also a total written amount of the memory is a predetermined upper limit value or greater.

3. The storage abnormality detection device of claim 1, wherein the determination section determines an abnormality of the memory in cases in which errors uncorrectable by the correction section have been detected the predetermined number of times or more in the predetermined period and also a predetermined manufacturer's warranty period or predetermined manufacturer's warranty distance has been exceeded.

4. The storage abnormality detection device of claim 1, wherein in cases in which the memory is utilized in a function related to vehicle travel, a function related to regulations, or a function related to security, the storage abnormality detection device further comprises a notification section configured to notify an abnormality of the memory in cases in which an abnormality of the memory has been determined by the determination section.

5. The storage abnormality detection device of claim 1, wherein the determination section checks the total written amount of the memory prior to performing a write operation to the memory, and in cases in which the total written amount of the memory is less than a predetermined upper limit value, determines an abnormality caused by something other than the limit in cases in which errors uncorrectable by the correction section have been detected the predetermined number of times or more in the predetermined period.

6. A storage abnormality detection method in which a computer performs processing comprising:
detecting errors uncorrectable by a correction section that detects and corrects errors occurring in a memory having a total written amount limit; and
determining an abnormality of the memory in cases in which the uncorrectable errors have been detected a predetermined number of times or more in a predetermined period of time.

7. A non-transitory computer-readable storage medium stored with a storage abnormality detection program that causes a computer to execute processing comprising:
detecting errors uncorrectable by a correction section that detects and corrects errors occurring in a memory having a total written amount limit; and
determining an abnormality of the memory in cases in which the uncorrectable errors have been detected a predetermined number of times or more in a predetermined period of time.
